(19) United States
(12) Patent Application Publication
(10) Pub. No.: US 2019/0097316 A1
(43) Pub. Date: Mar. 28, 2019

(54) ADJUSTING OPERATION OF ANTENNAS BASED ON CAPACITANCE

(71) Applicant: Cypress Semiconductor Corporation, San Jose, CA (US)

(72) Inventor: Francis Patrick Cruise, San Jose, CA (US)

(73) Assignee: Cypress Semiconductor Corporation, San Jose, CA (US)

(21) Appl. No.: 15/716,095

(22) Filed: Sep. 26, 2017

(51) Int. Cl. H01Q 3/22; G01R 27/26; H01Q 5/30

(52) U.S. Cl. CPC H01Q 3/22; H01Q 5/30; G01R 27/2605

(57) ABSTRACT

A computing device includes a processing device that adjusts the operating parameters of one or more antennas based on capacitances detected at the one or more antennas. Capacitance sensors measure the capacitances detected at the one or more antennas and generate capacitance data. The processing device may adjust operating parameters of one or more antennas, such as frequency/band, radiation pattern, power, angle diversity, space diversity, etc., based on the capacitance data.

### BACKGROUND

Capacitance sensing systems can sense electrical signals generated on electrodes that reflect changes in capacitance. Such changes in capacitance can indicate a touch event (e.g., the proximity of an object to particular electrodes). Capacitive sense elements may be used to replace mechanical buttons, knobs and other similar mechanical user interface controls. The use of a capacitive sense element allows for the elimination of complicated mechanical switches and buttons, providing reliable operation under harsh conditions. In addition, capacitive sense elements are widely used in modern customer applications, providing user interface options in existing products. Capacitive sense elements can range from a single button to a large number arranged in the form of a capacitive sense array for a touch-sensing surface.

Capacitive sense elements may also be used to detect the capacitance detected at different components of an electronic device or computing device. For example, capacitive sense elements may be used to determine the capacitance at a corner or and edge of a computing device. In another example, the capacitive sense elements may be used to determine the capacitance at a speaker/microphone of a computing device. Capacitive sense elements may also be referred to as capacitance sensors or capacitive sensors.

There are two typical types of capacitance: 1) mutual capacitance where the capacitance-sensing circuit measures the capacitance between two electrodes that are coupled to a sensing device; 2) self-capacitance where the capacitance-sensing circuit measures capacitance between one or more electrodes and a ground potential (e.g., ground or system-level potential).

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 illustrates a mutual capacitance measurement circuit, according to some embodiments of the present disclosure.

FIGS. 2A and 2B illustrate a first type of capacitive sensor for measuring self-capacitance that may be used with a capacitance sensing component, according to some embodiments of the present disclosure.

FIGS. 2C and 2D illustrate another type of capacitive sensor for measuring mutual capacitance between two electrodes that may be used with a capacitance sensing component, according to some embodiments of the present disclosure.

FIG. 3 is a block diagram illustrating an embodiment of a computing system that receives input from one or more capacitive sensors, according to some embodiments of the present disclosure.

FIG. 4A illustrates a wearable computing device, in accordance with some embodiments of the present disclosure.

FIG. 4B illustrates a computing device, in accordance with some embodiments of the present disclosure.

FIG. 4C illustrates an example table of capacitances, in accordance with some embodiments of the present disclosure.

FIG. 5A illustrates a computing device, in accordance with some embodiments of the present disclosure.

FIG. 5B illustrates an example polar plot, in accordance with some embodiments of the present disclosure.

FIG. 5C illustrates a computing device, in accordance with some embodiments of the present disclosure.

FIG. 5D illustrates a computing device, in accordance with some embodiments of the present disclosure.

FIG. 6 is a flow diagram of a method of adjusting the operating characteristics of a set of antennas, in accordance with some embodiments of the present disclosure.

### DETAILED DESCRIPTION

Computing devices, such as smart phones, cellular phones, tablet computers, laptop computers, portable gaming devices, etc., may be held and/or handled by users while in operation. For example, a user may hold a smart phone while making a phone call or while interacting with the smart phone's touchscreen. The user's body tissue (e.g., skin, muscle, flesh, bone, body fat, etc.) may be highly absorptive of the radio frequency (RF) signals used in wireless communications. For example, a RF signal in the 2.4 gigahertz (GHz) band (e.g., an RF signal having a frequency of 2.4 GHz) may have as much as 20 dB of attenuation if a user's bone is placed between a transmitter and a receiver. In another example, a RF signal in the 2.4 gigahertz (GHz) band may more than 50 dB of attenuation if the user's head is placed between a transmitter and a receiver. The user's body tissue may attenuate, absorb, block, and/or prevent RF signals from being transmitted and/or received. In addition, contact with or proximity to a user's body tissue may also load an antenna and degrade/decrease the performance of matching components (e.g., a matching circuit, an impedance matching network, etc.) coupled to the antenna. Other conductive objects may also affect the transmission and receipt of RF signals. For example, a metal or metallic object that is proximate (e.g., near, close, etc.) to or in contact with the antenna may affect the transmissions and receipt of RF signals.

Because user's body tissue (or other proximate conductive object) may affect the transmission and receipt of RF signals, it may be useful to determine whether one or more antennas are in close proximity to or in contact with the user's body tissue. The capacitance detected at an antenna may indicate how close the antenna is to the users' body tissue (or other conductive object that may attenuate or block RF signals). For example, the higher the capacitance detected at an antenna, the closer the antenna is to the user's body tissue, and vice versa. Based on the capacitances or changes in capacitances detected at a set of antennas, the operating characteristics of one or more of the antennas may be adjusted to reduce or compensate for the effect on the RF signals, caused by the user's body tissue. For example, the radiation pattern, frequency band, power (e.g., transmit power), etc., of one or more antennas may be adjusted. In another example, the set of antennas may be configured on a space diversity configuration or an angle diversity configuration. Adjusting the operating characteristics of one or more antennas may increase the effectiveness and/or efficiency of a computing device in transmitting/receiving RF signals. For example, adjusting the operating characteristics of one or more antennas may increase the likelihood that RF signals will be transmitted/received properly because the attenuation and/or blocking of the RF signals cause by a user's body tissue is reduced or compensated for. In another example, adjusting the operating characteristics of one or more antennas allow the computing device to use power (e.g., battery power) more efficiently because the computing device may waste less power attempting to receive and/or transmit RF signals using antennas that are close to a user's body tissue. In a further example, the computing device may use power (e.g., battery power) more efficiently because the computing device may reduce the transmit power if the computing device determines that a higher transmit power is not needed to overcome attenuation caused by a user's body tissue (or other conductive object) because one or more antennas are not in contact with or proximate to the user's body tissue (or other conductive object). Although the present disclosure may refer to a user's body tissue and to effects on RF signals caused by proximity/contact with a user's body tissue, a conductive object (e.g., a metal or metallic object) that is proximate/in contact with the antenna may also affect the RF signals (e.g., may attenuate or block RF signals). The examples, implementation, embodiments, etc., disclose herein may also compensate for the effects on RF signals caused by proximity/contact with a conductive object (e.g., caused by a proximate conductive object).

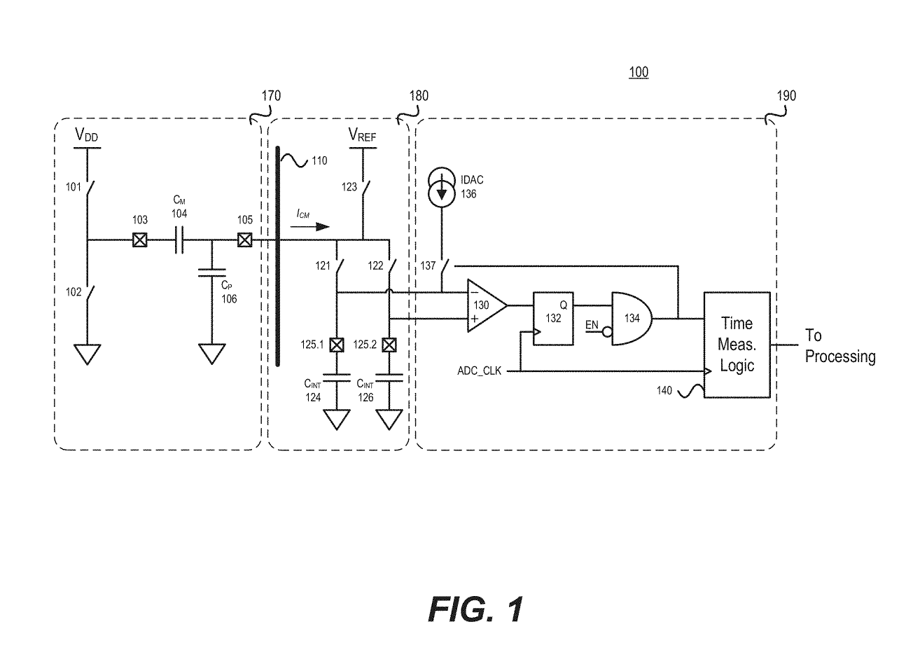

FIG. 1 illustrates a mutual capacitance measurement circuit 100, in accordance with some embodiments of the present disclosure. Mutual capacitance measurement circuit 100 may include a mutual capacitance circuit 170. Mutual capacitance circuit 170 may include a pair of switches, 101 and 102, coupled between a transmit (TX) pin 103 and a power supply and ground. TX pin 103 may be coupled to a first electrode of mutual capacitance (CM) 104 such that a TX signal generated by the alternating closures of switches 101 and 102 is applied to the first electrode. A second electrode of CM 104 may be coupled to a receive (RX) pin 105. The second electrode of CM 104 may be configured to receive a signal derived from the transmit signal applied to the first electrode of CM 104. RX pin 105 may be coupled to an integration circuit 180. A parasitic capacitance (Cp) 106 may exist between the second electrode, the RX pin, and the circuitry between RX pin and integration circuit 180. Cp 106 is not altered by the presence of a conductive object, but may still change and affect measurement; it is present on the circuit regardless of the state of the sensor. Different voltages may be applied as part of the TX signal. For example, a power supply voltage (VDD) of 1.8V may be boosted to provide the TX signal. In another example, the power supply voltage (VDD) may be divided down to provide the TX signal.

Integration circuit 180 may include a pair of integration capacitors 124 and 126 coupled to pins 125.1 and 125.2. Integration circuit 180 may include a pair of switches 121 and 122 coupled between integration capacitors 124 and 126 and RX pin 105. In one embodiment, RX pin 105 may be coupled to an analog multiplexor (AMUX) 110, which is coupled to integration circuit 180. In this embodiment, a single integration circuit may be used to measure multiple mutual capacitances that may exist between several electrodes of an array. In another embodiment, separate integration circuits may be assigned to each mutual RX pin. In this embodiment, more circuits may be necessary, but simultaneous measurement of multiple mutual capacitances may be possible. In still other embodiments, different combinations of RX pins and integration circuits may be implemented, including different numbers of RX pins assigned to integration circuits.

Integration circuit 180 may include a reference voltage, VREF, coupled to integration capacitors 124 and 126 through switch 123, switches 121 and 122, and pins 125.1 and 125.2. In one embodiment, VREF may be used to apply a known voltage to both integration capacitors 124 and 126 during an initialization phase. In various embodiments, different voltages may be used as VREF. In one embodiment, VREF may be a bandgap voltage. In other embodiments, VREF may be divided down from the power supply voltage (VDD), be a defined voltage of an integrated circuit, or be provided from an external power supply through an input pin of an integrated circuit including capacitance measurement circuit 100. Integration capacitors 124 and 126 may be coupled to a digitization circuit 190 through negative and positive inputs of comparator 130.

Comparator 130 of digitization circuit 190 may have an output coupled to D flip-flop 132 which may be used to avoid synchronization issues between analog components (such as comparator 130) and digital components used in the digitization of the capacitance on integration capacitors 124 and 126. AND gate 134 may enable or disable the digitization of the capacitance on integration capacitors 124 and 126 by controlling (enabling) time measurement logic 140 and switch 137. Switch 137, when closed may provide a current from current digital-to-analog converter (IDAC) 136 for charging integration capacitor 124. Unless “EN” is active high, time measurement logic 140 does not receive a signal from comparator 130 (through D flip-flop 132 and AND gate 134). As EN is active high only during the digitization phase, time measurement logic 140 does not receive signals during the integration and initialization phases.

In various embodiments, IDAC 136 may be fixed or programmable. In still other embodiments, IDAC 136 may be implemented a fixed current source through a resistor or as switched capacitor network. In an embodiment of a switched capacitor network, the current may be controlled by controlling the switching frequency of the switched capacitor.

In one embodiment, integration capacitors 124 and 126 may be disposed external to an integrated circuit including the switches and digitizing elements of mutual capacitance measurement circuit 100. In this embodiment, integration capacitors are coupled to the mutual capacitance measurement circuit 100 through pin 125.1 and 125.2. In another embodiment, integration capacitors 124 and 126 are part of the integration circuit and are implemented in silicon. In this embodiment, integration capacitors 124 and 126 are not coupled to pins 125.1 and 125.2 as they are already coupled to the mutual capacitance measurement circuit that exist in silicon.

The output of time measurement logic 140 may be passed to processing logic that may be used to compare mutual capacitance measured at a first time to that measured at a second time or to a baseline capacitance. Processing logic may be used to determine if a conductive object is present on or in proximity to electrodes that form CM 104. Processing logic may be on a separate device as capacitance measurement circuit 100, or it may be implemented as part of an integration circuit that also includes capacitance measurement circuit 100. This is discussed in more detail below.

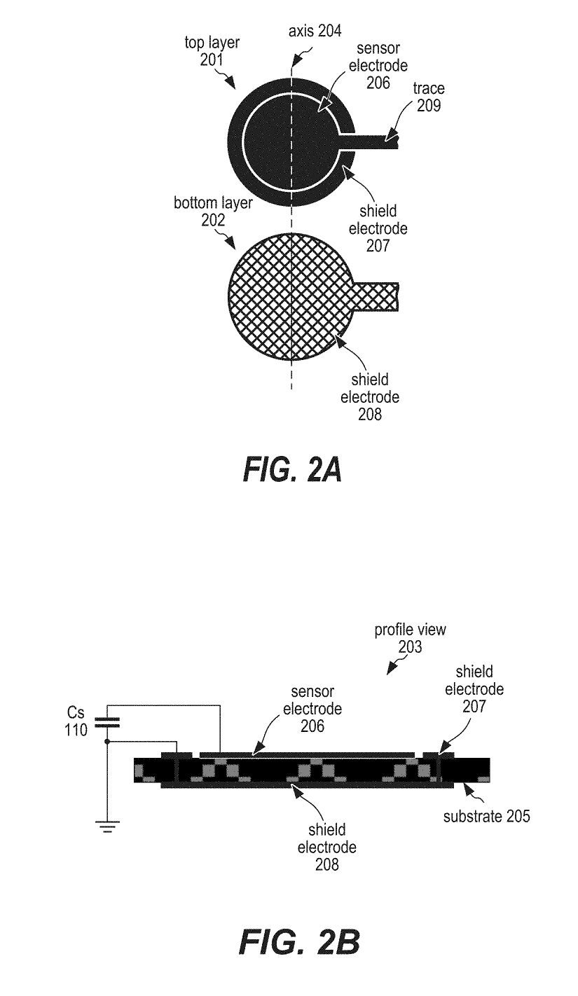

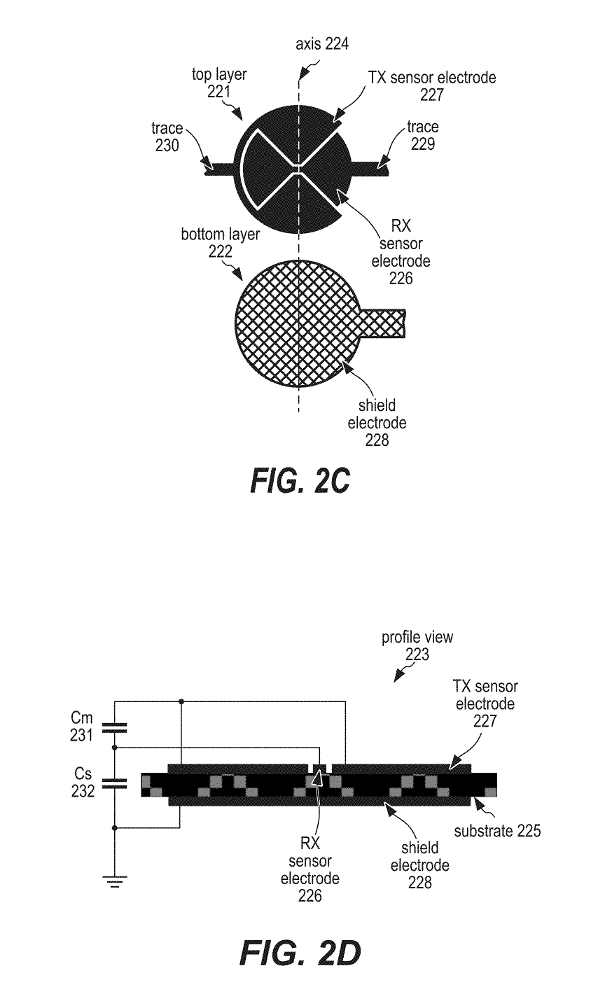

FIGS. 2A and 2B illustrate a first type of capacitive sensor for measuring self-capacitance that may be used with a capacitance sensing component, according to some embodiments of the present disclosure. FIG. 2A illustrates a top layer 201 and a bottom layer 202 of the self-capacitance sensor, while FIG. 2B illustrates a profile section view 203 of the sensor along axis 204. The self-capacitance sensor as illustrated in FIGS. 2A and 2B includes the circular patterns of conductive material in the top layer 201 and the bottom layer 202 which are attached to the top and bottom surfaces of a substrate 205, respectively. The top layer 201 includes a sensor electrode 206 that is substantially surrounded by a shield electrode 207 and that is electrically connected to a connecting trace 209 that extends past the shield electrode 207 and can be used for connecting the sensor electrode 206 to sensing circuitry in the capacitance sensing component. The bottom layer 202 includes a shield electrode 208 having a cross-hatched fill pattern that overlaps the area covered by electrode 206, electrode 207, and trace 209. The shield electrode 208 is electrically connected to the shield electrode 207, and the shield electrodes 207 and 208 are grounded.

With reference to the profile view 203, the self-capacitance Cs 210 represents a capacitance between the sensor electrode 206 and the shield electrodes 207 and 208. In one embodiment, the capacitance Cs 210 is in the range from 3 picofarads (pF) to 5 pF, and changes by at least 1 pF when the is touched by a conductive object such as a user's body tissue.

FIGS. 2C and 2D illustrate another type of capacitive sensor for measuring mutual capacitance between two electrodes that may be used with a capacitance sensing component, according to some embodiments of the present disclosure. FIG. 2C illustrates a top layer 221 and a bottom layer 222 of the mutual-capacitance sensor, while FIG. 2D illustrates a profile section view 223 of the sensor along axis 224. The mutual-capacitance sensor as illustrated in FIGS. 2C and 2D includes the patterns of conductive material in the top layer 221 and the bottom layer 222 which are attached to the top and bottom surfaces of a substrate 225, respectively. The top layer 221 includes a receive (RX) sensor electrode 226 that is capacitively coupled with a transmit (TX) sensor electrode 227. The TX sensor electrode 227 and the RX sensor electrode 226 are extended by traces 230 and 229, respectively, which can be used as connection points to connect the electrodes 227 and 226 to sensing circuitry in the capacitance sensing component. The bottom layer 222 includes a shield electrode 228 that is connected to ground and that overlaps the area covered by the RX electrode 226, TX electrode 227, and trace 229 with a cross-hatched fill pattern.

With reference to the profile view 223, the mutual capacitance Cm 331 represents a capacitance between the TX sensor electrode 227 and the RX sensor electrode 226, while the self-capacitance Cs 232 represents a capacitance between the RX sensor electrode 226 and the grounded shield electrode 228. In one embodiment, the mutual capacitance Cm 231 decreases in response to a conductive object touching or in the proximity of the boundary between the TX electrode 227 and the RX sensor electrode 226, while the self-capacitance Cs 232 increases.

In some embodiments, capacitive sensors as described above may be overlaid with a protective film, coating, or other material over the top layer of conductive material of the sensor. For example, a layer of plastic or glass may be used to protect the conductive material from direct contact. Thus, the sensor may detect a conductive object, such as a user's body tissue, that contacts the surface of the overlaid material rather than directly contacting the conductive material of the sensor.

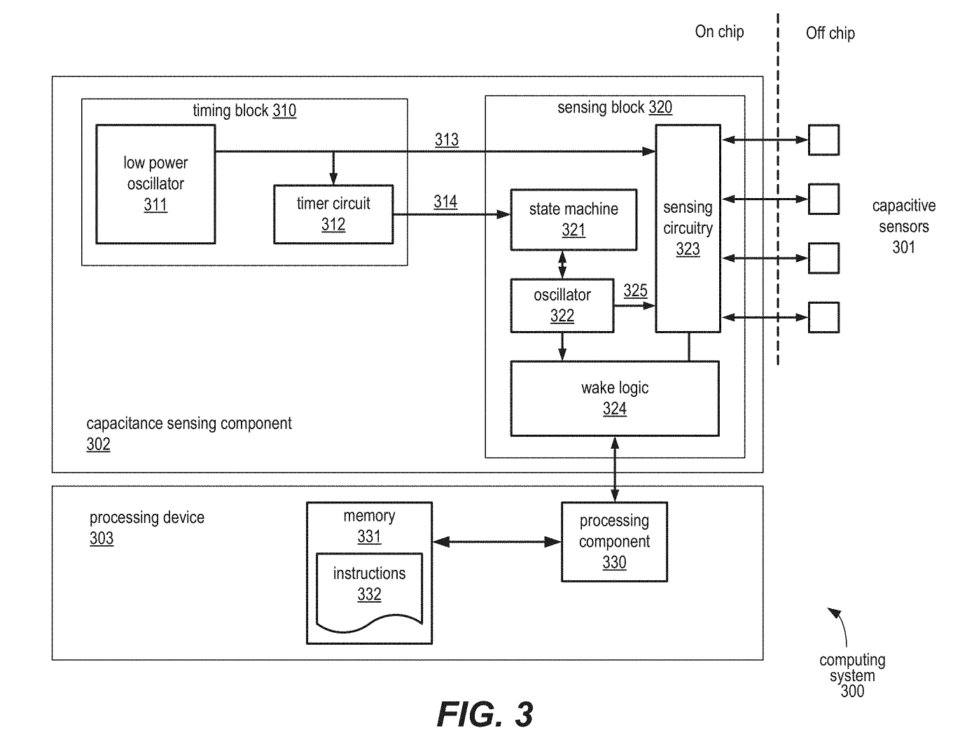

FIG. 3 illustrates a computing system 300, according to some embodiments of the present disclosure. Computing system 300 includes capacitive sensor 301, a capacitance sensing component 302, and a processing device 303. The capacitance sensing component 302 may operate on a different power domain than the processing device 303, so that the capacitance sensing component 302 may be operated in different power consumption states independently from the power consumption state of the processing device 303. Accordingly, the capacitance sensing component 302 may be operating during a sensor monitoring period in order to monitor touches at the capacitive sensor 301 even while the processing device 303 and/or the remainder of the computing system 300 is maintained in a low power consumption state, such as a suspend, standby, or hibernate state.

In one embodiment, the capacitance sensing component 302 includes a timing block 310 and a sensing block 320. The timing block 310 includes a low power oscillator 311 and a timer circuit 312 that run continuously to repeatedly trigger the sensing block 320 to determine whether a contact is present at any of the sensors 301 (i.e., determine whether a conductive object is contacting or in the proximity of one of the sensors 301).

The timer circuit 312 receives the clock signal 313 from the low power oscillator 311 and generates a repetitive trigger signal based on the clock signal 313. In one embodiment, the timer circuit may be implemented by a clock divider or a counter to generate a repetitive trigger signal having a frequency that is less than the frequency of the clock signal 313. In one embodiment, the repetitive trigger signal is a substantially periodic signal (i.e., having a fixed nominal period); in alternative embodiments, the repetitive trigger signal may be aperiodic.

The timing block 310 transmits the clock signal 313 and the repetitive trigger signal to the sensing block 320. In response to the repetitive trigger signal, the sensing block 320 initiates a measurement scan to determine whether a conductive object is in contact with or proximate to any of the capacitive sensors 301. For example, for a repetitive trigger signal that is implemented as a pulse train, the sensing block 320 may initiate a measurement scan in response to each pulse in the pulse train, and may perform the measurement scan by sequentially applying one of the clock signals 313 or 325 to each of the capacitive sensors 301 to measure their respective capacitance values during the measurement period.

The response of the sensing block 320 to the repetitive trigger signal is controlled by the state machine 321, which receives the repetitive trigger signal from the timer circuit 312. For example, the state machine 321 may respond to a pulse of the repetitive trigger signal by transitioning the sensing block 320 from a low power consumption state to a high power consumption state. In one embodiment, the low power consumption state is an operating mode of the sensing block 320 in which the components of the sensing block 320, such as the oscillator 322, sensing circuitry 323, and wake logic 324 are not operating and are drawing no current or minimal current. The state machine 321 may thus transition the sensing block 320 to a high power consumption state by causing power to be supplied to the oscillator 322, sensing circuitry 323, and/or wake logic 324. By turning on these components of the sensing block 320, the state machine 321 causes the oscillator 322 to generate a clock signal 325 for the sensing circuitry 323, and causes the sensing circuitry 323 to begin measurement of the capacitive sensors 301.

In one embodiment, the sensing circuitry 323 selects one of the clock signals or 325 and applies the selected clock signal to each of the capacitive sensors 301 in sequence to detect changes in capacitance resulting from a conductive object on or near any of the sensors 301. In one embodiment, the low power oscillator 311 consumes 10 nanoampere (nA) of current to generate the clock signal 313 having a frequency of 1 kHz, while the oscillator 322 consumes 1 microampere (μA) to generate the clock signal 325 having a frequency of 100 kHz.

The use of clock signal 313 instead of clock signal 325 may result in relatively lower power consumption and an increased measurement period, corresponding to a slower response time for detecting a sensor contact. In one embodiment where only the 1 kHz clock signal 313 is used, the oscillator 322 may also be omitted or maintained in the off state for all power consumption states to further reduce power consumption. The use of clock signal 325 instead of clock signal 313 may result in relatively higher power consumption, a shorter measurement period, and a quicker response time for detecting a sensor contact.

In one embodiment, the state machine 321 is additionally configured to transition the sensing block 320 back to the low power consumption state after the measurement scan is complete and before a next subsequent pulse after the most recent pulse of the repetitive trigger signal.

The sensing block 320 includes a wake logic 324 which is configured to cause the processing component 330 to transition from a low power consumption state to a high power consumption state in response to detecting the presence of the conductive object at the one or more of the capacitive sensor sensors 301. The wake logic 324 transition the processing device 303 from the low power consumption state to the higher power consumption state by outputting a wake signal to the processing component 330. For example, wake logic 324 may transition the processing component 330 from a low power consumption state that is an Advanced Configuration and Power Interface (ACPI) C3 ‘sleep’ power state to a high power consumption state that is an ACPI C0 ‘operating’ power state.

In one embodiment, the processing component 330 and/or other components of the processing device 303 are supplied power from a different power domain than the capacitance sensing component 302. By operating the capacitance sensing component 302 and processing device 303 on different power domains, the modules 302 and 303 can be powered up and powered down independently, and can operate in different power consumption states. In one embodiment, the processing device 303 is constructed on a different integrated circuit chip than the capacitance sensing component 302. For example, a first integrated circuit chip that is supplied power from a first power domain may include the timing block 310 and sensing block 320, while a second integrated circuit chip that is supplied power from a second power domain may include the processing component 330 and memory 331. In an alternative embodiment, the processing device 303 and the capacitance sensing component 302 can be located on the same integrated circuit chip.

In one embodiment, the wake logic 324 may determine whether a specific wake sequence has occurred, then output the wake signal to the processing device 303 in response to the wake sequence. A wake sequence may be defined as, for example, activation of a particular sensor or a combination or sequence of sensors. If a valid wake sequence is not detected, the wake logic 324 allows the processing component 330 to remain in the low power consumption state.

In one embodiment, the wake signal output from the wake logic 324 may also cause the processing device 303 to transition between low and high power consumption states, since the processing device 303 may include other components (such as memory 331) that can be switched between power states. For example, the wake signal may switch the processing device 303 between one of the ACPI G1 ‘sleeping’ power states and the ACPI G0 ‘working’ power state. In one embodiment, the processing component 330 may propagate the wake signal to the other components of processing device 303 in order to change the power consumption state of the processing device 303; alternatively, the wake signal may be received and processed by other logic in the processing device 303.

In one embodiment, the processing device 303 includes a memory 331 storing instructions 332 that are executable by the processing component 330. In one embodiment, the processing component 330 is configured to automatically execute the instructions 332 after transitioning from a low power consumption state to a high power consumption state. The processing component 330 may execute different sets of instructions depending on the specific wake sequence that is detected by the wake logic 324. For example, when the sensing block 320 detects a contact at a first capacitive sensor, the wake logic 324 may wake the processing component 330 and cause the processing component 330 to execute a first block of instructions, and when the sensing block 320 detects a contact at a second capacitive sensor, the wake logic 324 may wake the processing component 330 and cause the processing component 330 to execute a different block of instructions.

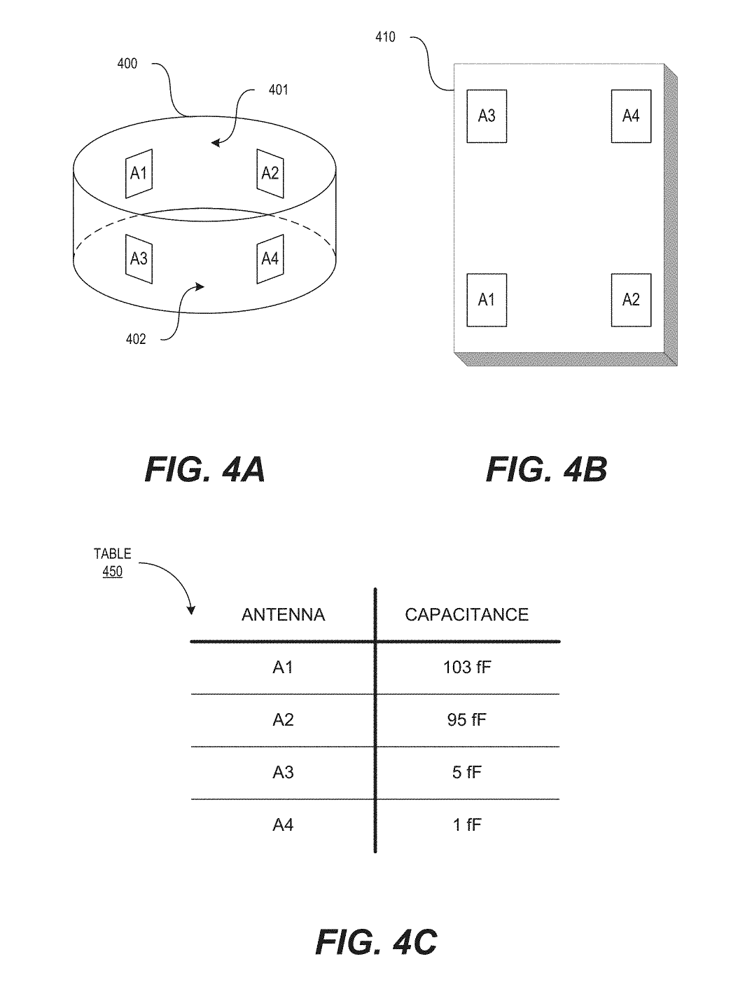

FIG. 4A illustrates a wearable computing device 400, in accordance with some embodiments of the present disclosure. Examples of wearable computing devices 400 may include a smart watch, a smart bracelet, wireless headphones, wireless headsets, a fitness/activity tracker, etc. The wearable computing device 400 may include a memory (not shown in FIG. 4A), a processing device (not shown in FIG. 4A), and antennas A1, A2, A3, and A4. The wearable computing device 400 may have the general shape of a bracelet, with an inner surface 401 (that may contact the skin of a user/wearer) and an outer surface 402. Antennas A1 and A2 may be located on the inner surface 401 of the wearable computing device 400. Antennas A3 and A4 may be located on the outer surface 402 of the wearable computing device. In some embodiments, the wearable device 400 may be reversible (e.g., flipped inside out) such that the outer surface 402 may become an inner surface and the inner surface 401 may become an outer surface.

The wearable computing device 400 may communicate data (e.g., transmit data and/or receive data) with other computing devices (e.g., a smart phone, a tablet computer, a laptop computer, a server computer, etc.) by transmitting and/or receiving RF signals via one or more of the antennas A1, A2, A3, and A4. Because the antennas A1 and A2 are located on the inner surface 401 of the wearable computing device 400, the antennas A1 and A2 may come into contact with and/or may be in close proximity to a user's body. As discussed above, the user's body tissue (e.g., skin, muscle, bone, body fat, etc.) may generally be highly absorptive of the RF signals that are transmitted and/or received by the antennas A1, A2, A3, and/or A4. In addition, the proximity of the user's body tissue may also load the antennas A1, A2, A3, and/or A4, and may degrade/decrease the performance of the matching components (e.g., impedance matching circuits, impedance matching networks, etc.).

FIG. 4B illustrates a computing device 410, in accordance with some embodiments of the present disclosure. The computing device 410 may be a portable computing device. Examples of a portable computing device may include a smartphone, a table computer, a music player, a handheld gaming device, etc. The computing device 410 may include a memory (not shown in FIG. 4B), a processing device (not shown in FIG. 4B), and antennas A1, A2, A3, and A4. The computing device 410 may have the general shape of a rectangular prism or a cuboid.

As discussed above, the computing device 410 may communicate data (e.g., transmit data and/or receive data) with other computing devices (e.g., a smart phone, a tablet computer, a laptop computer, a server computer, etc.) by transmitting and/or receiving RF signals via one or more of the antennas A1, A2, A3, and A4. As the user handles or holds the computing device 410 in different positions, the antennas A1, A2, A3, and/or A4 may come into contact with and/or may be in close proximity to a user's body. As discussed above, the user's body tissue (e.g., skin, muscle, bone, body fat, etc.) may generally be highly absorptive of the RF signals that are transmitted and/or received by the antennas A1, A2, A3, and A4. In addition, the proximity of the user's body tissue may also load the antennas A1, A2, A3, and A4 and may degrade/decrease the performance of the matching components (e.g., impedance matching circuits, impedance matching networks, etc.).

The embodiments, examples, implementations, etc., described herein may be applicable to various types of devices with different form factors, shapes, dimensions, sizes, etc. For example, the embodiments described herein may be applicable to a smart watch/bracelet. In another example, the embodiments described herein may be applicable to a smart necklace. In a further example, the embodiments described herein may be applicable to earphones, earbuds, headsets, etc. In another example, the embodiments described herein may be applicable to a smart pen/stylus. In a further example, the embodiments described herein may be applicable to various portable/mobile computing devices such as tablet computers, laptop computers, smart phones, handheld gaming devices, etc. In another example, the embodiments described herein may be applicable to any device that includes one or more antennas that may come into contact with or proximity to a conductive object (such as a user's body tissue).

FIG. 4C illustrates an example table 400 of capacitances, in accordance with some embodiments of the present disclosure. Table 400 may be an example of capacitance data. The first column of the table 400 indicates the antenna that is being measured by a capacitance sensor. Examples of capacitance sensors include mutual capacitance 104 illustrated in FIG. 1 and capacitive sensors illustrated in FIG. 2A through 2D. A capacitance sensor may also be referred to as a capacitive sensor. The second column of the table 400 indicates the capacitance that is detected by the capacitance sensor coupled to the respective antenna. For example, a capacitance (or change in capacitance) of 103 femtofarads (fF) is detected (e.g., measured) at antenna A1, a capacitance (or change in capacitance) of 95 fF is detected at antenna A2, a capacitance (or change in capacitance) of 5 fF is detected at antenna A3, and a capacitance (or change in capacitance) of 1 fF is detected at antenna A4. In one embodiment, the capacitances detected by the capacitance sensors may be relative capacitances. For example, the capacitances sensors may detect changes or differences in capacitances between a first point in time and a second point in time. In another embodiment, the capacitances detected by the capacitance sensors may be absolute capacitances. When the present disclosure refers to measuring capacitances, detecting capacitances, determining capacitances, etc., this may refer to relative capacitance (e.g., a change or difference in capacitance) or absolute capacitance.

The capacitances illustrated in table 400 may vary due to how close a user's body tissue is to a respective antenna. For example (referring to FIG. 4A), if the user wears the wearable device 400 on the user's wrist, the antennas A1 and A2 (which are located on the inner surface 401 of the wearable device 400) may be in contact with or in close proximity to the user's body tissue. This may result in a higher capacitance (or higher change in capacitance) detected at the antennas A1 and A2 (e.g., 103 fF and 95 fF respectively) than at the antennas A3 and A4 (e.g., 5 fF and 1 fF respectively). In another example (referring to FIG. 4B), if a user's hand is holding the lower half of the computing device 410 the user's hand may be in contact with or in close proximity to the antennas A1 and A2 (which are located on the lower half of the computing device 410). This may also result in a higher capacitance (or change in capacitance) detected at the antennas A1 and A2 (e.g., 103 fF and 95 fF respectively) than at the antennas A3 and A4 (e.g., 5 fF and 1 fF respectively).

In one embodiment, capacitance sensors may be coupled to the antennas A1, A2, A3, and A4. The capacitance sensors may detect the capacitances at the antennas A1, A2, A3, and A4. The capacitances at the antennas A1, A2, A3, and A4 may change as the antennas A1, A2, A3, and A4 come into contact or proximity with the user's body tissue. The processing device of the device 410 may receive capacitance data (which represent/indicate the capacitances or changes in capacitance at the antennas A1, A2, A3, and A4) and may adjust operating parameters of one or more of the antennas A1, A2, A3, and A4 based on the capacitance data (e.g., based on the capacitances or changes in capacitance detected at the antennas A1, A2, A3, and A4) based on the capacitance data, as discussed in more detail below. For example the antennas A1 through A4 may be configured to operate in a space diversity of angle diversity configuration based on the capacitance data, as discussed in more detail below. In another example, the power of an RF signal, radiation pattern, and/or frequency/band of an RF signal may be adjusted based on the capacitance data, as discussed in more detail below.

Examples of antennas may include, but are not limited to, wire antennas (e.g., monopole antennas, dipole antennas, loop antennas, etc.), microstrip antennas (e.g., planar inverted-f antennas (PIFA), patch antennas), near-field communication (NFC) antennas, fractal antennas, aperture antennas (e.g., slot antenna, inverted-F antenna), etc. Although four antennas are illustrated in FIGS. 4A though 4C, one having ordinary skill in the art understands that any different number of antennas may be used and different placements/orientations of the antennas may be used.

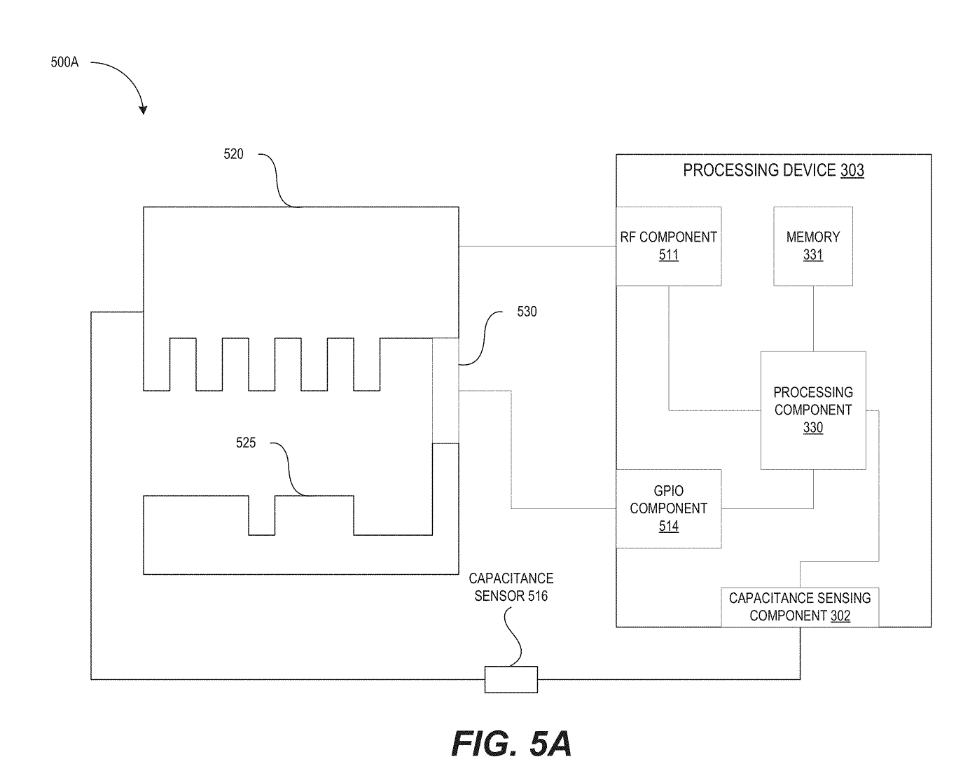

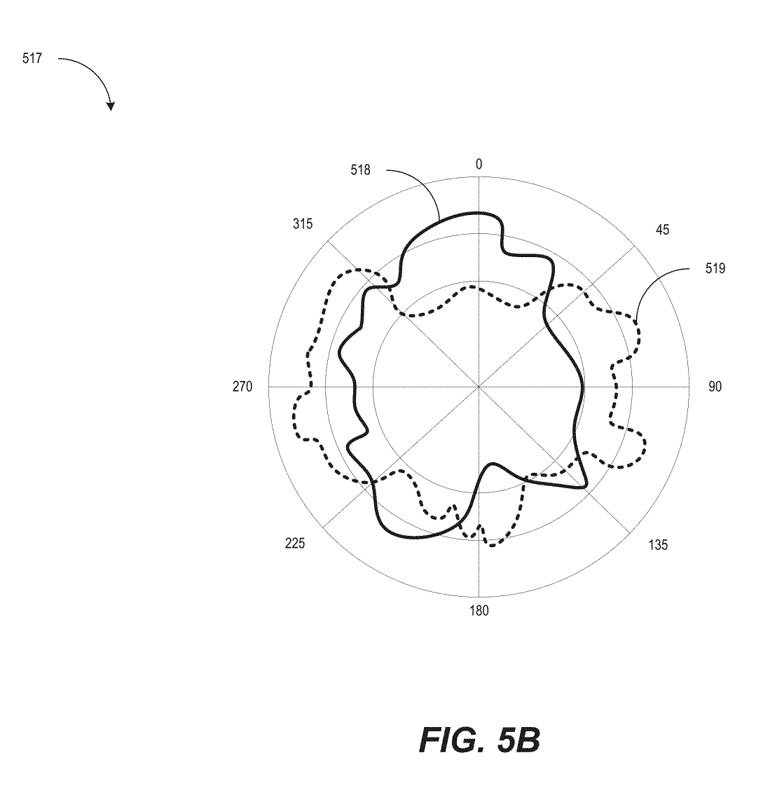

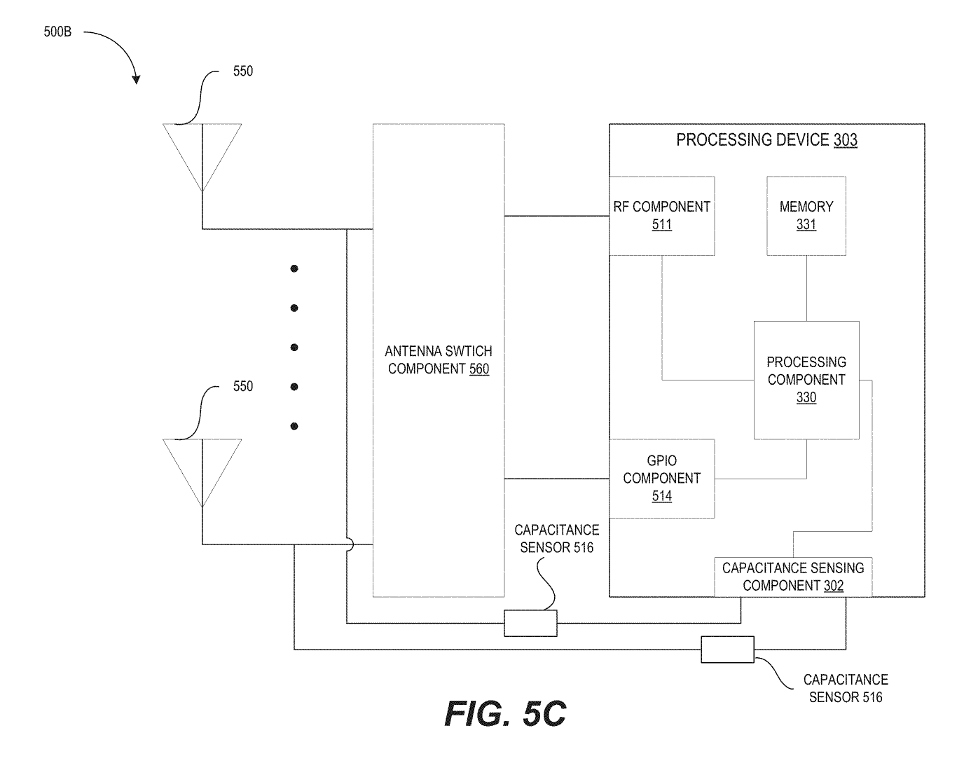

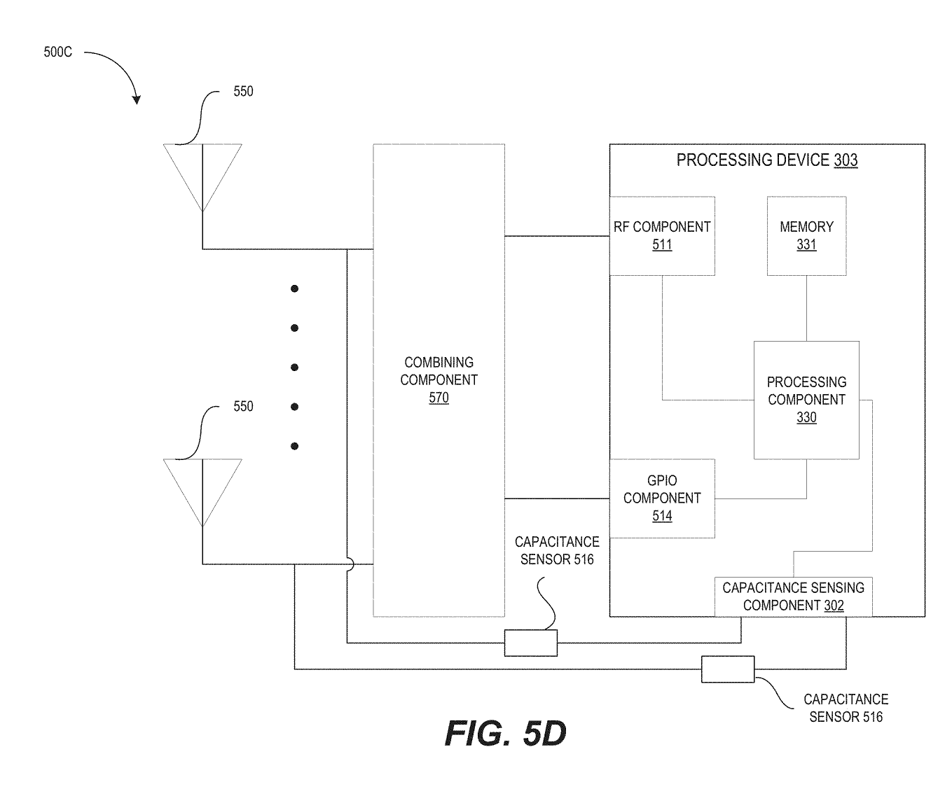

FIG. 5A illustrates a computing device 500A, in accordance with some embodiments of the present disclosure. Examples of computing devices include a smart phone, a cellular phone, a tablet computer, a laptop computer, etc. The computing device 500A includes a processing device 510, a capacitance sensor 516, an antenna 520, a stub 525, and a switch 530. The processing device 510 includes a RF component 511, a memory 331, a processing component 514, a general purpose input/output (GPIO) component 514, and a capacitance sensing component 515. The processing device 510 may be central processing unit (CPU), application specific integrated circuit (ASIC), a field programmable gate array (FPGA), a digital signal processor (DSP), a microprocessor, a microcontroller, a system-on-chip (SoC) a programmable SOC (PSoC), etc. The processing component 514 may be hardware, software, firmware, or a combination thereof, that may execute instructions. For example, the processing component 330 may be referred to as a processor core, an execution unit, etc. The stub 525 may be a metallic device/component (e.g., a shaped piece of metal or metallic alloy). The GPIO component 514 may be may be hardware, software, firmware, or a combination thereof, that may be used to communicate data (e.g., transmit or receive bits, binary signals, etc.) with other components of the computing device 500A.

The RF component 511 may generate RF signals and may provide the RF signals to the antenna 520. The RF component 511 may also receive RF signals received (e.g., detected) by the antenna 520 and may process the RF signals. Examples of RF component 511 may include an RF radio, such as a Bluetooth® radio a Wi-Fi™ radio (e.g., a 802.11b radio, a 802.11ac radio, a 802.11n radio, etc.).

The antenna 520 may transmit RF signals to other computing devices and/or may receive RF signals from other computing devices, as discussed above. The antenna 520 may be a monopole antenna, a PIFA antenna, a microstrip antenna, etc. The capacitance sensor 516 may be coupled to the antenna 520 (e.g., electrically coupled, coupled via a wire, pin, line, trace, etc.). In one embodiment, the antenna 520 may be a multimode antenna. A multimode antenna may be an antenna that may be configured to change one or more of its frequency of operation (e.g., the band/frequency of RF signals that are transmitted/received), its radiation pattern, or its polarization. A multimode antenna may also be referred to as a reconfigurable antenna.

The capacitance sensor 516 may detect the capacitance at the antenna 520 and/or may detect the changes in capacitance at the antenna 520, as discussed above. Examples of capacitance sensors include mutual capacitance 104 illustrated in FIG. 1 and capacitive sensors illustrated in FIG. 2A through 2D. The capacitances sensor 516 may generate capacitance data (e.g., signals, values, numbers, other information, etc.) that may indicate the capacitances (or changes in capacitance) detected at the antenna 520. The capacitance sensor 516 may provide the capacitance data to the capacitance sensing component 515. The capacitance sensing component 515 may process the capacitance data and/or may store the capacitance data in the memory 331 (e.g., in cache, random-access memory, registers, flash memory, etc.). In one embodiment, the capacitance sensing component 515 may generate the capacitance data based on signals and/or other data received from the capacitance sensor 516. For example, the capacitance sensing component 515 may generate a value (e.g., 100) indicating a capacitance (or change in capacitance) detected by the capacitance sensor 516. Although the memory 331 is illustrated as part of the processing device 510, the memory 331 may be separate from the processing device 510 in other embodiments. In addition, although the capacitance sensor 516 is illustrated as separate from the processing device 303, the capacitance sensor 516 may be part of the processing device 303 in other embodiments.

As discussed above, the capacitance data may indicate the capacitance (or change in capacitance) detected at the antenna 520. A higher capacitance (or change in capacitance) may indicate that the antenna 520 is in contact with and/or in proximity to human body tissue (e.g., skin, muscle, etc.). The processing component 330 may adjust one or more operating characteristics of the antenna 520 based on the capacitance data, as discussed above. For example, if the capacitance (or change in capacitance) detected at the antenna 520 is greater than a threshold capacitance (or a threshold change in capacitance), the processing component 330 may adjust one or more operating characteristics of the antenna 520.

In one embodiment, the processing component 330 may adjust the operating characteristics of the antenna 520 by changing the radio pattern of the RF signals generated/transmitted by the antenna 520. The processing component 330 may communicate with the GPIO component 514 and/or may cause the GPIO component 514 to activate/deactivate (e.g., turn on/turn off) the switch 530. Activating the switch 530 may couple (e.g., electrically couple, connect, etc.) the antenna 525 to the stub 525. Deactivating the switch 530 may decouple (e.g., electrically decouple, disconnect, etc.) the stub 525 from the antenna 520. Coupling the stub 525 to the antenna 520 and decoupling the stub 525 from the antenna 520 may change the radiation pattern of the RF signals generated/transmitted by the antenna 520. For example, the shape of the radiation pattern may be changed, as discussed in more detail below. In another example, the orientation and/or direction of the radiation pattern may be changed, as discussed in more detail below.

In another embodiment, the processing component 330 may change the frequency/band of the RF signals that is generated/transmitted by the antenna 520. For example, the processing component 330 may communicate with the RF component 511 and may cause/instruct the RF component 511 to generate RF signals at a different frequency/band.

In a further embodiment, the processing component 330 may change the power of an RF signal transmitted by the antenna 520. For example, the processing component 330 may increase the power of the RF signal (e.g., increase the transmit power, increase the amplitude, etc.) if a higher capacitance is detected at the antenna 520. The increase in the power of the RF signal may allow the antenna 520 to transmit and/or receive RF signals despite the attenuation or blocking caused by the contact/proximity with the user's body tissue (e.g., may allow the computing device 500A to compensate for the attenuation caused by the user's body tissue).

In a further embodiment, the processing component 330 may change two or more of the frequency/band of the RF signal, the radiation pattern of the RF signal, and the power of the RF signal. For example, if a higher capacitance (or change in capacitance) is detected at the antenna 520, the processing component 330 may use an RF signal with a smaller bandwidth (such as the 802.11b standard which has a 22 megahertz (MHz) RF bandwidth) and may transmit the RF signal at a higher power. In another example, if a lower capacitance (or change in capacitance) is detected at the antenna 520, the processing component 330 may use an RF signal with a higher bandwidth (such as the 802.11ac standard which has a 160 megahertz (MHz) RF bandwidth and may transmit the RF signal at a lower power.

In one embodiment, the processing component 330 may refrain from transmitting and/or receiving RF signals if the capacitance (or change in capacitance) detected at the antenna 520 is greater than a threshold capacitance (or threshold change in capacitance). For example, the processing component 330 may cause the RF component 511 to stop generating/transmitting RF signals if the capacitance (or change in capacitance) at the antenna 520 is greater than a threshold capacitance or capacitance change because the proximity of the antenna 520 to the user's body tissue will prevent the RF signal from being received by a computing device, and power (e.g., battery power) can be saved by not transmitting the RF signal. In one embodiment, refraining from transmitting and/or receiving RF signals may be an example of adjusting one or more operating characteristics of one or more antennas.

FIG. 5B illustrates an example polar plot 517, in accordance with some embodiments of the present disclosure. As discussed above, a processing device or computing device may adjust the operating characteristics of an antenna changing the radio pattern of the RF signals generated/transmitted by the antenna. Referring to FIG. 5A, the antenna 520 may generate/transmit an RF signal with the radiation pattern 518 when the switch 530 is activated and the stub 525 is coupled to the antenna 520. The antenna 520 may also generate/transmit an RF signal with the radiation pattern 519 when the switch 530 is deactivated and the stub 525 is decoupled from the antenna 520. As illustrated in FIG. 5B, the shape of the radiation pattern 518 is different from the shape of the radiation pattern 519. The orientation and/or direction of the radiation pattern 518 may also be different than orientation of the radiation pattern 519. For example, the radiation pattern 518 may come upward or out of the FIG. 5B while the radiation pattern 519 may go downward or into the FIG. 5B. Changing the direction, orientation, and/or shape of the radiation pattern of the RF signal may allow the computing device to transmit and/or receive RF signals more effectively, more efficiently and/or with less power consumption. For example, if the user's body tissue is below the antenna 520 changing the radiation pattern such that the radiation pattern comes upward/away from the user's body tissue may allow the computing device to transmit and/or receive data with less attenuation from the user's body (e.g., may allow the computing device to compensate for the effect on RF signals, such as attenuation, caused by the user's body).

FIG. 5C illustrates a computing device 500B, in accordance with some embodiments of the present disclosure. Examples of computing devices include a smart phone, a cellular phone, a tablet computer, a laptop computer, etc. The computing device 500A includes a processing device 510, a set of capacitance sensors 516, a set of antennas 550 (e.g., one or more antennas), and an antenna switch component 560. The processing device 510 includes a RF component 511, a memory 331, a processing component 514, a GPIO component 514, and a capacitance sensing component 515, as discussed above.

One or more of the antennas 550 may transmit RF signals to other computing devices and/or may receive RF signals from other computing devices, as discussed above. A capacitance sensor 516 may be coupled to each of the antennas 550 (e.g., electrically coupled, coupled via a wire, pin, line, trace, etc.) or a subset of the antennas 550 may be respectively coupled to a capacitance sensor 516. The capacitance sensors 516 may detect the capacitances and/or changes in capacitances at the antennas 550, as discussed above. The capacitances sensors 516 may generate capacitance data (e.g., signals, values, numbers, other information, etc.) that may indicate the capacitances or changes in capacitance detected at the antennas 550 and may provide the capacitance data to the capacitance sensing component 515. The capacitance sensing component 515 may process the capacitance data and/or may store the capacitance data in the memory 331. In one embodiment, the capacitance sensing component 515 may generate the capacitance data based on signals and/or other data received from the capacitance sensor 516, as discussed above. In addition, although the capacitance sensors 516 are illustrated as separate from the processing device 303, the capacitance sensors 516 may be part of the processing device 303 in other embodiments.

As discussed above, a higher capacitance (or change in capacitance) may indicate that a respective antenna 550 is in contact with and/or in proximity to human body tissue (e.g., skin, muscle, etc.). The processing component 330 may adjust one or more operating characteristics of one or more of the antennas 550 based on the capacitance data, as discussed above. For example, if the capacitance (or change in capacitance) detected at a first antenna 550 is greater than a threshold capacitance (or threshold change in capacitance), the processing component 330 may adjust one or more operating characteristics of the first antenna 550.

In one embodiment, the processing component 330 may adjust the operating characteristics of the antennas 550 by configuring the antennas 550 to operate in a space diversity configuration. A space diversity configuration may be a configuration where a subset of the antennas 550 is used to transmit and/or receive RF signals. For example, referring to FIG. 4C, the computing device 500B may have four antennas 550 (represented in the table 400 as antennas A1 through A4) and the capacitance (or change in capacitance) detected at two of the antennas 550 (e.g., antenna A1 and A2) may be greater than a threshold capacitance (or threshold change in capacitance) because the two antennas 550 are in contact with or in close proximity to a user's body tissue. The processing component 330 may use one or more of the remaining two antennas (e.g., antenna A3 and A4) to transmit and/or receive wireless signals because the remaining two antennas may be least likely to experience attenuation caused by the user's body tissue (which may allow the computing device 500B to transmit/receive RF signals more effectively, more efficiently, and with less power consumption). This may allow the computing device 500B to compensate for the effects on RF signals (e.g., attenuation of RF signals) caused by the user's body tissue.

In one embodiment, the processing component 330 may cause and/or instruct the antenna switch component 560 to couple one or more of the antennas 550 to the RF component 511 based on the capacitance data. For example, the processing component 330 may cause and/or instruct the antenna switch component 560 to couple (e.g., electrically couple, connect, etc.) one of the antennas 550 to the RF component 511. In another example, the processing component 330 may cause and/or instruct the antenna switch component 560 to couple three of the antennas 550 to the RF component 511. In a further example, the processing component 330 may cause and/or instruct the antenna switch component 560 to couple the antenna 550 with the smallest capacitance (or change in capacitance) to the RF component 511. Coupling an antenna 550 to the RF component 511 may enable, activate, or turn on the antenna 550 which may allow the antenna to transmit/receive RF signals. Decoupling the antenna from the RF component may disable, deactivate, or turn off the antenna 550 which may prevent the antenna from transmitting/receiving RF signals.

In one embodiment, the processing component 330 may refrain from transmitting and/or receiving RF signals if all of the capacitances (or changes in capacitance) detected at the antennas 550 are greater than a threshold capacitance (or threshold change in capacitance), as discussed above. Because all of the antennas 550 are in contact with or in proximity to the user's body tissue, the RF signals transmitted by the antennas 550 will likely not be received (due to the effects on the RF signals caused by the user's body tissue). This may allow the computing device 500B to save power (e.g., battery power) by not transmitting/receiving RF signals. In one embodiment, refraining from transmitting and/or receiving RF signals may be an example of adjusting one or more operating characteristics of one or more antennas.

FIG. 5D illustrates a computing device 500C, in accordance with some embodiments of the present disclosure. Examples of computing devices include a smart phone, a cellular phone, a tablet computer, a laptop computer, etc. The computing device 500A includes a processing device 510, a set of capacitance sensors 516, a set of antennas 550 (e.g., one or more antennas), and a combining component 570. The processing device 510 includes a RF component 511, a memory 331, a processing component 514, a general purpose input/output (GPIO) component 514, and a capacitance sensing component 515, as discussed above. One or more of the antennas 550 may transmit RF signals to other computing devices and/or may receive RF signals from other computing devices, as discussed above. A capacitance sensor 516 may be coupled to each of the antennas 550, as discussed above. The capacitance sensors 516 may detect the capacitances and/or changes in capacitances at the antennas 550 and may generate capacitance data, as discussed above. The capacitance sensing component 515 may process the capacitance data and/or may store the capacitance data in the memory 331, as discussed above. In one embodiment, the capacitance sensing component 515 may generate the capacitance data based on signals and/or other data received from the capacitance sensor 516, as discussed above. In addition, although the capacitance sensors 516 are illustrated as separate from the processing device 303, the capacitance sensor s516 may be part of the processing device 303 in other embodiments.

As discussed above, a higher capacitance (or change in capacitance) may indicate that a respective antenna 550 is in contact with and/or in proximity to human body tissue (e.g., skin, muscle, etc.). The processing component 330 may adjust one or more operating characteristics of one or more of the antennas 550 based on the capacitance data, as discussed above. For example, if the capacitance (or change in capacitance) detected at one or more antennas 550 is greater than a threshold capacitance (or threshold change in capacitance), the processing component 330 may adjust one or more operating characteristics of or more antennas 550.

In one embodiment, the processing component 330 may adjust the operating characteristics of the antennas 550 by configuring the antennas 550 to operate in an angle diversity configuration. An angle diversity configuration may be a configuration where RF signals received on multiple antennas 550 are combined to obtain a combined RF signal. An angle diversity configuration may also be a configuration where RF signals are transmitted on multiple antennas 550 at different phases. For example, referring to FIG. 4C, the computing device 500C may have four antennas 550 (represented in the table 400 as antennas A1 through A4) and the capacitance (or change in capacitance) detected at two of the antennas 550 (e.g., antenna A1 and A2) may be greater than a threshold capacitance (or threshold change in capacitance) because the two antennas 550 are in contact with or in close proximity to a user's body tissue. The processing component 330 may cause the RF signals received/detected by the remaining two antennas (e.g., antenna A3 and A4) to be combined because the remaining two antennas may be least likely to experience attenuation caused by the user's body tissue (which may allow the computing device 500C to transmit/receive RF signals more effectively, more efficiently, and with less power consumption). The processing component 330 may also cause the RF signals transmitted by the remaining two antennas to have different phases (e.g., to be phase-shifted). This may allow the computing device 500C to compensate for the effect on the RF signals (e.g., the attenuation of RF signals) caused by the user's body tissue.

In one embodiment, the processing component 330 may cause and/or instruct the combining component 570 to combine the RF signals received from the antennas 550 (via GPIO component 514) based on the capacitance data. For example, the processing component 330 may instruct the combining component 570 to combine the RF signals using equal gain combining (e.g., a simple average of the RF signals received). In another example, the processing component 330 the processing component 330 may instruct the combining component 570 to combine the RF signals using maximal ratio combining (e.g. a weighted average of the signals received). The processing component 330 may instruct the combining component 570 to use specific weights for the maximal ratio combining, based on the capacitance data. For example, referring to FIG. 4C, the processing component 330 may instruct the combining component 570 to combine the RF signals received from the antennas A3 and A4 using the formula RF_COMB=0.8 (RF_A4)+0.2 (RF_A3), where RF_COMB is the combined RF signal, where RF_A3 is the RF signal received from the antenna A3, and RF_A4 is the RF signal received from the antenna A4. A higher weight (e.g., 0.8) may be used for the antenna A4 because the lowest capacitance (or change in capacitance) is detected at antenna A4 (compared to antenna A3). In some embodiments, the weights used for the maximal ration combining may be proportional or ratiometric to the capacitance (or change in capacitance) detected at the antennas 550.

In one embodiment, the processing component 330 may refrain from transmitting and/or receiving RF signals if all of the capacitances or capacitance changes detected at the antennas 550 are greater than a threshold capacitance or threshold capacitance changes, as discussed above. Because all of the antennas 550 are in contact with or in proximity to the user's body tissue, the RF signals transmitted by the antennas 550 will likely not be received (due to the effects on the RF signals caused by the user's body tissue). This may allow the computing device 500C to save power (e.g., battery power) by not transmitting/receiving RF signals. In one embodiment, refraining from transmitting and/or receiving RF signals may be an example of adjusting one or more operating characteristics of one or more antennas.

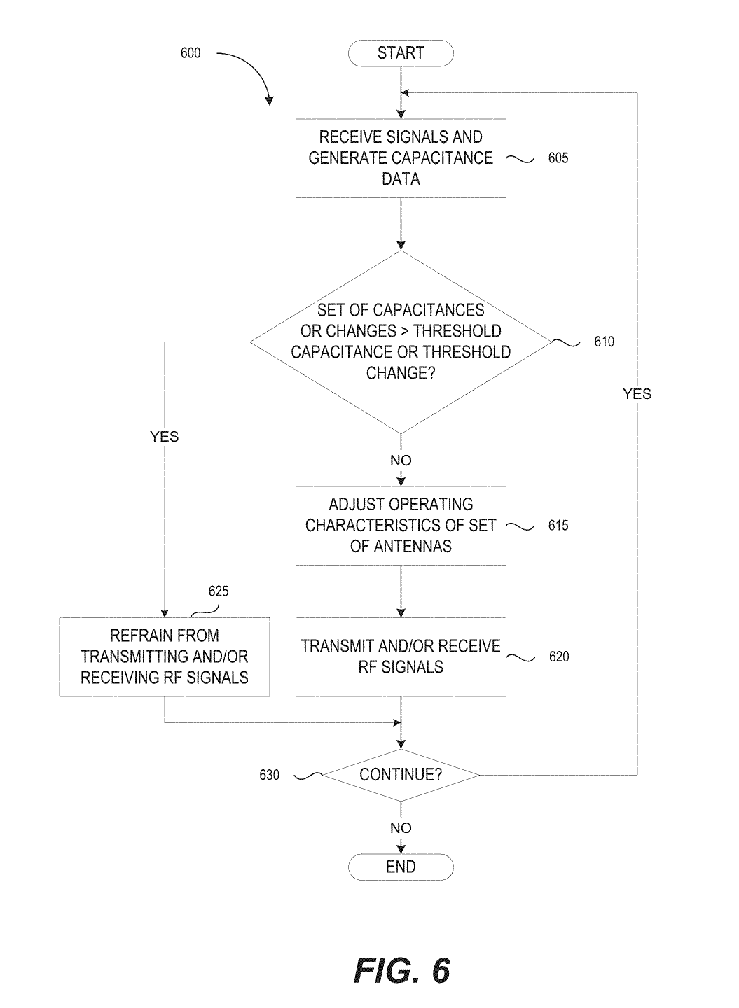

FIG. 6 is a flow diagram of a method 600 of adjusting the operating characteristics of a set of antennas, according to some embodiments of the present disclosure. Method 600 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. In some embodiments, the method 600 may be performed by a processing device (e.g., processing device 303 illustrated in FIG. 3), a processing component (e.g., processing component 330 illustrated in FIG. 3), a processing device (e.g., processing device 510 illustrated in FIGS. 5A, 5C, and 5D) and/or a processing component (e.g., processing component 330 illustrated in FIGS. 5A, 5C, and 5D).

The method 600 begins at block 605, where the processing device receives one or more signals from a set of capacitance sensors. The processing device may generate capacitance data based on the one or more signals receive from the set of capacitance sensors (e.g., one or more capacitance sensors). As discussed above, the capacitance data may indicate one or more capacitances (or changes in capacitance) detected or measured at one or more antennas of a computing devices (e.g., one capacitance or change in capacitance for each of the one or more antennas). The processing device may optionally store the capacitance data in a memory (e.g., a random access memory, a cache, a flash memory, etc.). At block 610, the processing device determines whether the set of capacitances or capacitance changes is greater than a threshold capacitance or threshold capacitance change. For example, the processing device may determine whether each change in capacitance (detected at each antenna) in the set of changes in capacitances is greater than the threshold change in capacitance.

The processing device may proceed to block 625 if all of the capacitances (or changes in capacitance) in the set of capacitances are greater than the threshold where the processing device may refrain from transmitting and/or receiving RF signals. For example, the processing device may instruct an RF component (e.g., an RF radio) to stop generating/transmitting RF signals. In another example, the processing device may instruct the RF component to stop detecting/processing RF signals. As discussed above, if an antenna is in contact with or in close proximity to a user's body tissue, this may affect the antenna's ability to receive and/or transmit RF signals (e.g., because the user's body tissue will absorb and/or attenuate the RF signals). If all of the capacitances (or changes in capacitance) in the set of capacitances are greater than the threshold capacitance (or threshold change in capacitance), this may indicate that there is no antenna that is not in contact with or in close proximity to a user's body tissue (e.g., a user's skin, muscle, etc.). The processing device may refrain from transmitting and/or receiving RF signals (on all of the one or more antennas) because the user's body tissue may affect the transmission/receipt of the RF signals (e.g., may prevent the RF signals from being sent/received properly). In one embodiment, refraining from transmitting and/or receiving RF signals may be an example of adjusting one or more operating characteristics of one or more antennas.

The processing device may adjust the operating characteristics of one or more of antennas at block 615 if at least one of the capacitances (or changes in capacitance) in the set of capacitances is not greater than the threshold capacitance (or threshold change in capacitance). For example, the processing device may configure the set of antennas to operate in a space diversity configuration (e.g., transmit/receive using a subset of the antennas) based on the capacitance data, as discussed above. In another example, the processing device may configure the set of antennas to operate in an angle diversity configuration (e.g., combine RF signals received by different antennas or transmit RF signals at different phases for different antennas) based on the capacitance data, as discussed above. In a further example, the processing device may change the radiation pattern of one or more of the antennas based on the capacitance data, as discussed above. In yet another example, the processing device may change the frequency/band used by one or more antennas based on the capacitance data, as discussed above. In another example, the processing device may change the power (e.g., transmit power, amplitude, etc.) of the RF signal transmitted by one or more antennas based on the capacitance data, as discussed above. If at least one of the capacitances (or changes in capacitance) in the set of capacitances in the set of capacitances is not greater than the threshold capacitance or threshold change in capacitance (e.g., is less than or equal to the threshold capacitance or threshold change in capacitance), this may indicate that there at least one antenna that is not in contact with or is not in close proximity to a user's body tissue (e.g., a user's skin, muscle, etc.). The at least one antenna may be able to transmit and/or receive wireless signals with less interference than the other antennas that are in contact/proximity to the user's body tissue. Adjusting one or more operating parameters of one or more antennas may allow the computing device to reduce or compensate for the effects on RF signals (e.g., attenuation, blocking, absorption, etc., of RF signals) caused by the user's body tissue. The processing device may proceed to block 620 after adjusting the operating characteristics of one or more of the set of antennas and may transmit and/or receive RF signals using the configured antennas.

At block 630, the processing device may determine whether to continue receiving capacitance data, processing/analyzing the capacitance data, and adjusting the operating characteristics of one or more antennas based on the capacitance data. For example, the processing device may determine whether it should periodically receive new capacitance data and adjust the operating characteristics of one or more antennas based on the capacitance data. A configuration setting/parameter on the computing device may indicate to the processing device whether the processing device should periodically receive new capacitance data and adjust the operating characteristics of one or more antennas. If the processing device determines that it should continue receiving capacitance data and adjusting operating characteristics of the antennas, the processing device may proceed to block 605. If the processing device determines that it should not continue receiving capacitance data and adjusting operating characteristics of the antennas, the method 600 ends.

Unless specifically stated otherwise, terms such as “receiving,” “adjusting,” “configuring,” “changing,” “enabling,” “disabling,” “combining,” “determining,” “refraining,” or the like, refer to actions and processes performed or implemented by computing devices that manipulates and transforms data represented as physical (electronic) quantities within the computing device's registers and memories into other data similarly represented as physical quantities within the computing device memories or registers or other such information storage, transmission or display devices.

Examples described herein also relate to an apparatus for performing the operations described herein. This apparatus may be specially constructed for the required purposes, or it may comprise a general purpose computing device selectively programmed by a computer program stored in the computing device. Such a computer program may be stored in a computer-readable non-transitory storage medium.

Certain embodiments may be implemented as a computer program product that may include instructions stored on a machine-readable medium. These instructions may be used to program a general-purpose or special-purpose processor to perform the described operations. A machine-readable medium includes any mechanism for storing or transmitting information in a form (e.g., software, processing application) readable by a machine (e.g., a computer). The machine-readable medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory; or another type of medium suitable for storing electronic instructions. The machine-readable medium may be referred to as a non-transitory machine-readable medium.

The methods and illustrative examples described herein are not inherently related to any particular computer or other apparatus. Various general purpose systems may be used in accordance with the teachings described herein, or it may prove convenient to construct more specialized apparatus to perform the required method steps. The required structure for a variety of these systems will appear as set forth in the description above.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Also, the terms “first,” “second,” “third,” “fourth,” etc., as used herein are meant as labels to distinguish among different elements and may not necessarily have an ordinal meaning according to their numerical designation. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

1-20. (canceled)

21. An apparatus, comprising:
a radio-frequency component configured to generate radio-frequency signals and process radio-frequency signals;
a capacitance sensing component configured to generate capacitance data based on signals received from a set of capacitance sensors, wherein the capacitance data indicates a set of capacitances or indicates a set of changes in capacitance detected for a set of respective antennas; and
a processing component, coupled to the radio-frequency component and the capacitance sensing component, the processing component configured to compensate for attenuation caused by a proximate conductive object, wherein to compensate for the attenuation, the processing component is further configured to adjust a set of operating characteristics of a subset of the set of respective antennas based on the capacitance data, wherein the subset comprises fewer antennas than the set of respective antennas.

22. The apparatus of claim 21, wherein a first antenna of the set of respective antennas comprises a multimode antenna.

23. The apparatus of claim 22, wherein to adjust the set of operating characteristics, the processing device is configured to:
adjust a radiation pattern of the first antenna.

24. The apparatus of claim 22, wherein to adjust the set of operating characteristics, the processing device is configured to:
change the frequency band used by the first antenna.

25. The apparatus of claim 21, wherein to adjust the set of operating characteristics, the processing device is configured to:
configure the set of respective antennas to operate in a space diversity configuration.

26. The apparatus of claim 25, wherein to configure the set of respective antennas to operate in the space diversity configuration, the processing device is configured to:
enable a first antenna of the set of respective antennas; and
disable a second antenna of the set of respective antennas.

27. The apparatus of claim 21, wherein to adjust the set of operating characteristics, the processing device is configured to:
configure the set of respective antennas to operate in an angle diversity configuration.

28. The apparatus of claim 27, wherein to configure the set of respective antennas to operate in an angle diversity configuration, the processing device is configured to:
combine radio frequency signals received by a first antenna and a second antenna.

29. The apparatus of claim 21, wherein to adjust the set of operating characteristics, the processing device is configured to:
adjust a power of a radio frequency signal transmitted by a first antenna of the set of respective antennas.

30. The apparatus of claim 21, wherein the processing device is further configured to:
determine whether the set of capacitances is greater than a threshold capacitance or whether the set of changes in capacitance is greater than a threshold change in capacitance; and
refrain from transmitting or receiving radio frequency signals via the set of respective antennas in response to determining that the set of capacitances is greater than the threshold capacitance or that the set of changes in capacitance is greater than the threshold change in capacitance.

31. The apparatus of claim 21, wherein adjusting the set of operating characteristics is further based on determining that a first capacitance of the set of capacitances is not greater than the threshold capacitance or that a first change in the set of changes in capacitance is not greater than the threshold change in capacitance.

32. A method, comprising:
receiving one or more signals from a capacitance sensor;
generating capacitance data based on the one or more signals, wherein the capacitance data indicates a capacitance detected for antenna of a set of antennas; and
compensating for attenuation caused by a proximate conductive object by adjusting an operating characteristic of the first antenna, based on the capacitance data.

33. The method of claim 32, wherein the first antenna comprises a multimode antenna.

34. The method of claim 33, wherein adjusting the operating characteristic comprises one or more of:
adjusting a radiation pattern of the first antenna; or
changing the frequency band used by the first antenna.

35. The method of claim 32, wherein adjusting the operating characteristic comprises:
configuring the set of antennas to operate in a space diversity configuration, wherein the set of antennas comprises the antenna.

36. The method of claim 35, wherein configuring the set of antennas to operate in the space diversity configuration comprises:
enabling the first antenna of the set of antennas; and
disabling a second antenna of the set of antennas.

37. The method of claim 32, wherein adjusting the operating characteristic comprises:
configuring the set of antennas to operate in an angle diversity configuration, wherein the set of antennas comprises the antenna.

38. The method of claim of claim 37, wherein configuring the set of antennas to operate in the angle diversity configuration comprises:
combining radio frequency signals received by the first antenna and a second antenna.

39. The method of claim 32, further comprising:
determining whether the capacitance is greater than a threshold capacitance; and
refraining from transmitting or receiving radio frequency signals via the first antenna in response to determining that the capacitance is greater than the threshold capacitance.

40. A system, comprising:
a set of antennas configured to transmit and receive radio frequency signals;
a set of capacitance sensors coupled to the set of respective antennas;
a memory configured to store capacitance data, wherein the capacitance data indicates a set of capacitances detected for the set of respective antennas;
a processing device configured to:
receive one or more signals from the set of capacitance sensors;
generate the capacitance data based on the one or more signals; and
compensate for attenuation caused by a proximate conductive object, wherein to compensate for the attenuation, the processing devices is further configured to adjust a set of operating characteristics of a subset of the set of respective antennas based on the capacitance data, wherein the subset comprises fewer antennas than the set of respective antennas.
